(19) United States
(12) Patent Application Publication
(10) Pub. No.: US 2024/0210480 A1
(43) Pub. Date: Jun. 27, 2024

(54) METHOD OF ESTIMATING FULL CHARGE CAPACITY AFTER DEGRADATION OF BATTERY, AND METHOD OF CREATING ESTIMATING EQUATION FOR FULL CHARGE CAPACITY AFTER DEGRADATION

(71) Applicant: TOYOTA JIDOSHA KABUSHIKI KAISHA, Toyota-shi (JP)

(72) Inventors: Kumiko NODA, Toyota-shi (JP); Kouichi YOKOYAMA, Toyota-shi (JP)

(73) Assignee: TOYOTA JIDOSHA KABUSHIKI KAISHA, Toyota-shi (JP)

(21) Appl. No.: 18/497,609

(22) Filed: Oct. 30, 2023

(30) Foreign Application Priority Data
Dec. 27, 2022 (JP) 2022-209536

(51) Int. Cl. G01R 31/367; G01R 31/392; G07C 5/10

(52) U.S. Cl. CPC G01R 31/367; G01R 31/392; G07C 5/10; B60L 58/12

(57) ABSTRACT

Through an experiment or the like, a degradation contribution relation representing a relation between each of N battery state-related variables and a decrease in full charge capacity is obtained. Historical data on the variables is collected from L battery electric vehicles, and L simple estimated values of full charge capacity after degradation are obtained by using the degradation contribution relations. A correlation coefficient between the L historical data sets on each variable and the L simple estimated values is calculated, and M variables having the correlation coefficient exceeding a predetermined threshold are selected. An equation is formulated where the selected variables are explanatory variables and a high-accuracy estimated value of full charge capacity after degradation is an objective variable. The coefficients are determined by substituting K historical data sets into the variables of the equation and substituting K simple estimated values into a left side of the equation.

### CROSS-REFERENCE TO RELATED APPLICATION

This application claims priority to Japanese Patent Application No. 2022-209536 filed on Dec. 27, 2022, incorporated herein by reference in its entirety.

### BACKGROUND

### 1. Technical Field

A technique disclosed by the present description relates to a method of estimating a full charge capacity after degradation of a battery mounted in a battery electric vehicle, and a method of creating an estimating equation for a full charge capacity after degradation.

### 2. Description of Related Art

The full charge capacity of a long-used battery decreases from a full charge capacity at the beginning of use (an initial value of full charge capacity) due to degradation. Full charge capacity becomes smaller than an initial value thereof also when a battery is left unused for a long time. In the present description, the full charge capacity of a battery after a predetermined time period is referred to as “full charge capacity after degradation”. An example of a technique of estimating a full charge capacity after degradation is disclosed in Japanese Unexamined Patent Application Publication No. 2020-042036. The method of JP 2020-042036 A uses a charge-discharge history of a battery to estimate a full charge capacity after degradation thereof.

### SUMMARY

The present description provides a technique of estimating a full charge capacity after degradation of a battery with higher accuracy than conventional methods.

A large number of variables can affect battery degradation. Typical examples of the variables are an unattended period and an energization amount of a battery. It cannot be found only from battery history information how much each variable contributes to degradation. The technique disclosed by the present description selects a variable that more largely contributes to battery degradation from among many variables related to a battery state. A full charge capacity after degradation is estimated by using the selected variable.

One technique disclosed by the present description provides a method of creating an estimating equation for a full charge capacity after degradation. The method includes seven steps as follows.

First step: A degradation contribution relation is obtained through an experiment or simulation. The degradation contribution relation represents a relation between each of N variables related to a battery state and how much full charge capacity decreases from an initial value thereof depending on the variable. Hereinafter, a decrease in full charge capacity from the initial value thereof will be referred to as capacity decrease. Second step: Historical data on the variables is collected from L battery electric vehicles, and a simple estimated value of full charge capacity after degradation for each of the L battery electric vehicles is obtained by using the degradation contribution relations. More specifically, a capacity decrease is obtained with respect to each variable by substituting actual values of each variable into the corresponding degradation contribution relation. The simple estimated value of full charge capacity after degradation can be obtained by subtracting the N capacity decreases from the initial value of full charge capacity.

Third step: A correlation coefficient between L sets of the historical data on each variable and the L simple estimated values is calculated, and M variables having the correlation coefficient that exceeds a predetermined threshold value are selected. Fourth step: By using the selected variables, Equation 1 is formulated by which a high-accuracy estimated value of current full charge capacity is obtained. Equation 1 corresponds to a multiple regression equation where the high-accuracy estimated value is an objective variable, and the M variables are explanatory variables.

$$\begin{matrix}[ Formula 1 ] & \\ High - accuracy estimated value = initial full charge capacity - {\sum }_{i = 1}^{M} ( coefficient ( i ) \times variable ( i ) ) + constant & ( Equation 1 )\end{matrix}$$

Fifth step: The coefficients and a constant of Equation 1 are determined by substituting each set of K sets of the historical data (each set of the historical data includes actual values of the M variables), among the L sets of the historical data, into the variables of Equation 1 and substituting K simple estimated values corresponding to the K sets of the historical data into the left side of Equation 1. Sixth step: The coefficients are corrected in such a manner that a correlation between (L−K) high-accuracy estimated values and (L−K) simple estimated values corresponding to the (L−K) high-accuracy estimated values becomes stronger. The (L−K) high-accuracy estimated values are obtained by substituting (L−K) sets of the historical data into the right side of Equation 1 including the determined coefficients and constant. Seventh step: Equation 1 using the corrected coefficients is obtained as an estimating equation for a full charge capacity after degradation.

The method has characteristics as follows. In the first step, a degradation contribution relation is obtained with respect to each variable through an experiment or simulation. Through the first step, it becomes clear how much each individual variable contributes to battery degradation (capacity decrease). In the second step and the third step, variables that more largely contribute to the capacity decrease are selected by using simple estimated values and historical data. Among many variables, only the variables that largely contribute to degradation can be extracted. After the third step, an estimating equation for a full charge capacity after degradation is obtained through multiple regression analysis.

A method of estimating a full charge capacity after degradation of a battery by using Equation 1 as described above is also one technique disclosed by the present description.

In the fifth step, the coefficients may be determined by using reinforcement learning. An example of the reinforcement learning is a genetic algorithm.

Details of and further improvements in the technique disclosed by the present description will be described in DETAILED DESCRIPTION OF EMBODIMENTS below.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a flowchart of a procedure of creating an estimating equation;

FIG. 2 is the flowchart of the procedure of creating the estimating equation (continued from FIG. 1);

FIG. 3A is a graph showing an example of a degradation contribution relation;

FIG. 3B is a graph showing an example of the degradation contribution relation;

FIG. 4A is a graph showing an example of a correlation between a variable and a simple estimated value;

FIG. 4B is a graph showing an example of a correlation between a variable and the simple estimated value;

FIG. 5A is a diagram describing correction of coefficients of a multiple regression equation; and

FIG. 5B is a diagram describing the correction of the coefficients of the multiple regression equation.

### DETAILED DESCRIPTION OF EMBODIMENTS

A battery mounted in a battery electric vehicle is degraded due to effects of various variables related to the states of a battery electric vehicle and a battery. Examples of the variables include a period for which a battery is not charged or discharged (unattended period), a period for which a battery is charged (or discharged) (energization period), an amount of electricity flowing through a battery (energization amount), a travel period of a battery electric vehicle, a travel distance of a battery electric vehicle, and the like. Each of such variables contributes to battery degradation. The values (that is, historic data) of such variables can be acquired from a battery electric vehicle that is actually traveling. However, a degree of battery degradation cannot be accurately estimated from historic data if it is not known how much each variable contributes to battery degradation. Note that as described above, the full charge capacity of a battery after a predetermined time period is adopted as an indicator of degradation. In other words, in the present description, full charge capacity after a predetermined time period is referred to as “full charge capacity after degradation”. For example, for a battery that had an initial full charge capacity of 300 [kAh] and currently has a full charge capacity of 250 [kAh], it is understood that the full charge capacity decreases by 50 [kAh] due to degradation.

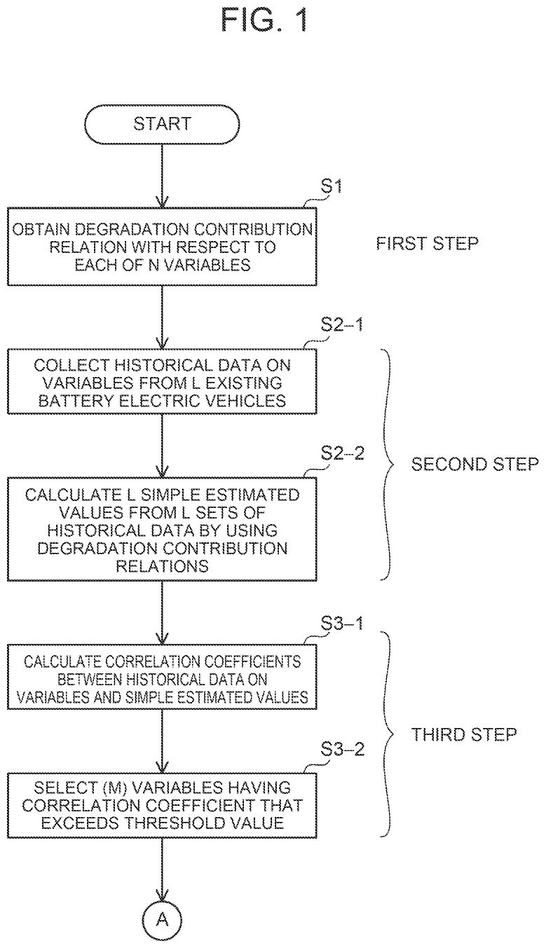

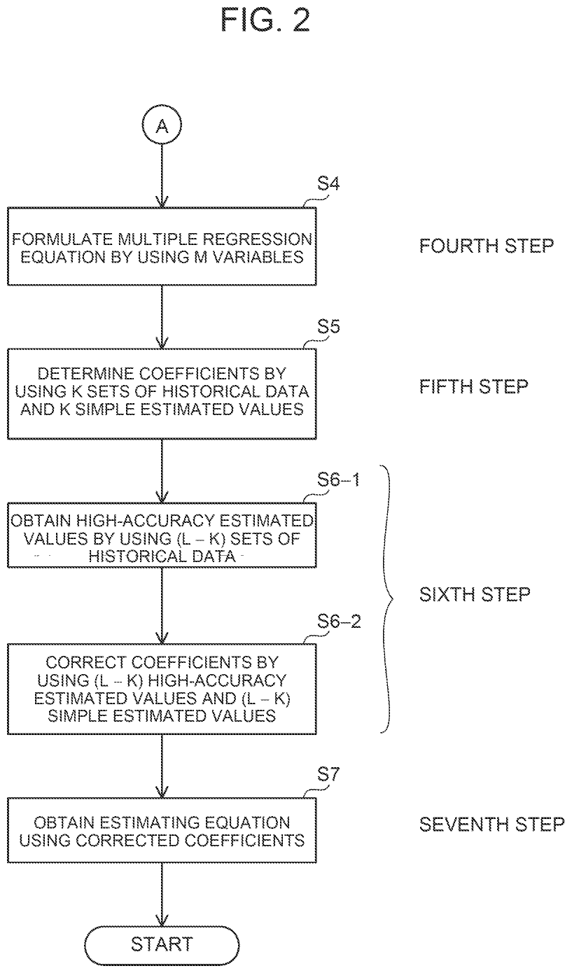

A method (an estimating equation for a full charge capacity of a battery) according to an embodiment is described with reference to the drawings. FIGS. 1, 2 show a flowchart illustrating a procedure of creating the estimating equation. The method of creating the estimating equation includes seven steps.

### First Step

It is examined, through an experiment or simulation, how much each of a plurality of battery state-related variables affects battery degradation. As described earlier, battery degradation is represented by a decrease in full charge capacity from an initial value thereof. Hereinafter, the decrease in full charge capacity from the initial value thereof is also referred to as capacity decrease in some cases. A relation between each variable and the capacity decrease is referred to as degradation contribution relation.

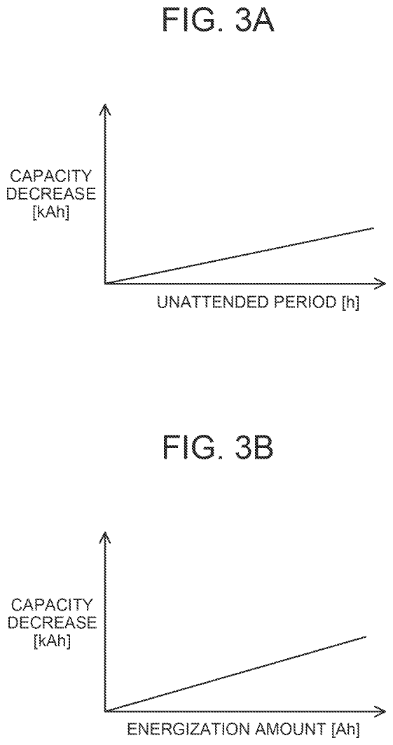

Examples of the degradation contribution relation are shown in FIGS. 3A, 3B. FIG. 3A is a graph showing a relation between the unattended period and the capacity decrease. In other words, the degradation contribution relation is a relational expression that determines a capacity decrease against historical data on a variable. FIG. 3B is a graph showing a relation between the energization amount and the capacity decrease. As the unattended period becomes longer, the capacity decrease increases. As the energization amount becomes larger, the capacity decrease also increases. Such degradation contribution relations can be obtained through an experiment or simulation by changing only a target variable with other variables kept unchanged. The square root of the unattended period and the square root of the energization amount may be adopted as variables. The unattended period and the energization amount in each predetermined temperature segment may be adopted as variables.

Here, the number of variables that are considered is assumed to be N. A degradation contribution relation is obtained with respect to each of the N variables (step S1). N degradation contribution relations are obtained.

### Second Step

Steps S2-1 and S2-2 in FIG. 1 correspond to a second step. First, historical data on the variables is collected from L battery electric vehicles that are already used (step S2-1). The historical data on the N variables refers to actual values of each variable on each battery electric vehicle. A communication device is mounted in each battery electric vehicle. Each battery electric vehicle periodically transmits historical data on the N variables to a management center. A computer of the management center collects the historical data on the variables from the L battery electric vehicles.

Subsequently, the computer of the management center calculates a simple estimated value of full charge capacity after degradation for each of respective batteries of the L battery electric vehicles by using the degradation contribution relations (step S2-2). For the battery of each battery electric vehicle, the computer substitutes the historical data on each variable into the corresponding degradation contribution relation, thus obtaining a capacity decrease corresponding to the historical data on each variable. In other words, N capacity decreases are obtained for the battery of each battery electric vehicle. The computer obtains the simple estimated value by subtracting the N capacity decreases from an initial value of the full charge capacity of each battery. The simple estimated value corresponds to an estimated value of full charge capacity after degradation calculated by using the degradation contribution relations and the historical data on the variables. The reason that the then estimated value is referred to as “simple estimated value” is because a higher-accuracy estimated value is obtained later.

For each of the batteries of the L battery electric vehicles, the computer obtains the simple estimated value. In other words, the computer obtains L simple estimated values. Each of the simple estimated values is obtained from the respective corresponding historical data. The L simple estimated values correspond to the L sets of historical data, respectively.

### Third Step

Steps S3-1 and S3-2 in FIG. 1 correspond to a third step. The computer calculates a correlation coefficient between each variable and the simple estimated value (step S3-1). Each of the L sets of historical data includes actual values of the N variables. In other words, for each of the N variables, L sets of historical data exist. In still other words, for each variable, the computer has L sets of data including the simple estimated value and actual values of the variable. The computer plots the L sets of data on a two-dimensional plane, with the simple estimated value represented by a vertical axis (or horizontal axis), and the actual values of a variable represented by a horizontal axis (or vertical axis). From the plotted L sets of data, the computer obtains the correlation coefficient between the simple estimated value and the actual values of the variable.

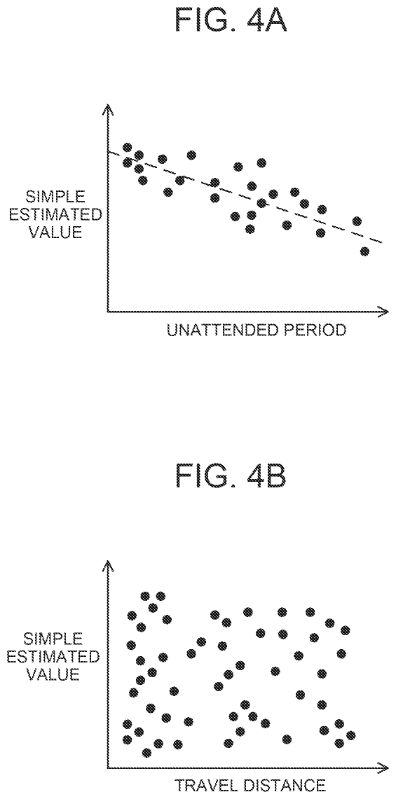

Examples of a correlation between a variable and the simple estimated value are shown in FIGS. 4A, 4B. FIG. 4A shows a relation between the simple estimated value and the unattended period. From FIG. 4A, it can be seen that there is a strong correlation between the simple estimated value and the unattended period. FIG. 4B shows a relation between the simple estimated value and the travel distance. The plotted travel distance against the simple estimated value disperses over the entire graph, and it can be understood that there is no correlation between the two.

The correlation coefficient is represented by a numerical value ranging from −1.0 to 1.0. A correlation coefficient closer to 1.0 (or −1.0) indicates a stronger correlation. When the correlation coefficient is zero, there is no correlation. Generally, when the correlation coefficient is smaller than −0.4 or is larger than 0.4, it is determined that there is a significant correlation between two variables (in the present case, the simple estimated value and a variable). When the correlation coefficient is a positive value (or negative value), it is recognized that there is a positive correlation (or negative correlation) between two variables. Since a method of obtaining a correlation coefficient is well known, a description thereof is omitted.

Subsequently, the computer selects a variable having a correlation coefficient that exceeds a threshold value (step S3-2). For example, the computer selects a variable having a correlation coefficient that is smaller than −0.4 and a variable having a correlation coefficient that is larger than 0.4. In other words, the computer selects a variable having a correlation coefficient of which the absolute value exceeds the threshold value (0.4).

For convenience of description, the number of variables selected is assumed to be M. In other words, of the N variables, (N−M) variables do not have significant effect on degradation of full charge capacity. Accordingly, after the selection, the computer excludes the (N−M) variables from the estimating equation for a full charge capacity of a battery. By using the selected M variables, the computer creates an equation for estimating a full charge capacity after degradation.

### Fourth Step

Step S4 in FIG. 2 corresponds to a fourth step. By using the M variables, the computer formulates a multiple regression equation for estimating a full charge capacity. The multiple regression equation is shown earlier as Equation 1. The left side of Equation 1 corresponds to an estimated value (high-accuracy estimated value) of full charge capacity after degradation. The right side of the multiple regression equation includes each variable (variable (i)), a coefficient (coefficient (i)) by which each variable is multiplied, and a constant. An initial full charge capacity on the right side of Equation 1 is a designed value of a battery and is already known.

The high-accuracy estimated value on the left side of Equation 1 corresponds to an objective variable of the multiple regression equation, and the variable (i) on the right side of Equation 1 corresponds to an “explanatory variable” of the multiple regression equation. On the then right side, each coefficient and the constant are unknowns.

### Fifth Step

Step S5 in FIG. 2 corresponds to a fifth step. The computer selects K sets of historical data from among the L sets of historical data. The computer determines the coefficients of the multiple regression equation by using the K sets of historical data and the respective simple estimated values corresponding to the individual sets of historical data (step S5). There is no rule applied when the K sets of historical data are selected from among the L sets of historical data. The computer may select the K sets of historical data arbitrarily from among the L sets of historical data. A simple estimated value is associated with each of the K sets of historical data. The computer substitutes the simple estimated value into the left side of Equation 1, and substitutes the historical data (actual values of each variable) into each variable on the right side. K equations are obtained in which M coefficients and one constant are unknowns. The computer determines the M coefficients and one constant by using the K equations.

A number larger than “M+1” is chosen for “K”. Since the multiple regression equation includes (M+1) unknowns, a system of (M+1) or more equations is needed to determine the unknowns. Since a method of obtaining coefficients of a multiple regression equation (that is, multiple regression analysis) is well known, a description thereof is omitted. When “K” is sufficiently (specifically, ten or more times) larger than “M+1”, a method of determining coefficients by using reinforcement learning is preferable. For a specific example of the reinforcement learning, it is preferable to use a genetic algorithm to obtain the coefficients.

### Sixth Step

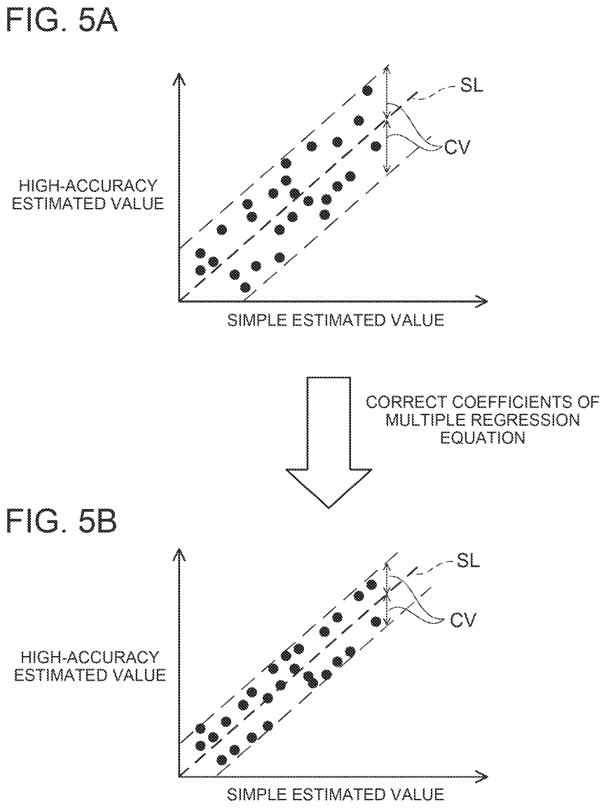

Steps S6-1 and S6-2 in FIG. 2 corresponds to a sixth step. (L−K) sets of historical data are not used in determining the coefficients of the multiple regression equation (Equation 1). The computer corrects the coefficients by using the (L−K) sets of historical data and the respective corresponding simple estimated values. The computer substitutes values of the variables in the (L−K) sets of historical data into Equation 1, thus obtaining (L−K) high-accuracy estimated values. For the then Equation 1, the coefficients and the constant determined in the fifth step are used. The computer plots pairs of each obtained high-accuracy estimated value and a simple estimated value corresponding to the high-accuracy estimated value on a two-dimensional plane. Both the simple estimated values and the high-accuracy estimated values are estimated values of full charge capacity after degradation obtained from the historical data, and therefore have linear correspondences with a slope of 45 degrees. In other words, the simple estimated values and the high-accuracy estimated values have a correlation. FIG. 5A is a diagram in which the pairs of a simple estimated value and a high-accuracy estimated value are plotted. A dashed line SL is a single regression line for the plotted (L−K) pairs, and a range indicated by a sign CV indicates the strength of correlation. A narrower range indicated by the sign CV indicates a stronger correlation.

The computer corrects the coefficients of Equation 1 (multiple regression equation) in such a manner that the plotted (L−K) pairs come closer to the dashed line SL. For example, the computer obtains a mean error and a maximum error of the plotted (L−K) pairs. The computer shifts the coefficients of Equation 1 at random and, when the mean error and the maximum error become the smallest, determines the then coefficients as corrected coefficients.

### Seventh Step

Equation 1 acquired through steps S1 to S6-2 is obtained as the estimating equation for a full charge capacity after degradation of a battery (step S7).

An estimated value of full charge capacity after degradation (current full charge capacity) of a battery of another battery electric vehicle can be obtained by acquiring historical data on the variables of the other battery electric vehicle and substituting the historical data into Equation 1.

The method includes characteristics and advantages as follows. In the first step, a degradation contribution relation is obtained with respect to each variable through an experiment or simulation. Through the first step, it becomes clear how much each individual variable contributes to battery degradation (capacity decrease). In the second step and the third step, variables that more largely contribute to the capacity decrease are selected by using simple estimated values and historical data. Among many variables, only the variables that largely contribute to the capacity decrease are extracted, whereby the number of terms of the multiple regression equation (Equation 1) is made smaller. In other words, the amount of calculation for determining coefficients of the multiple regression equation can be reduced. Through the steps after the third step, an estimating equation for a full charge capacity after degradation is obtained through multiple regression analysis.

Points to note related to the technique described in the embodiment are described. The number L of sets of historical data is larger than the number N of variables. Moreover, the number K of sets of historical data used to determine the coefficients included in Equation 1 is larger than the number M of variables selected. More preferably, the number K of sets of historical data is ten or more times larger than the number M of variables selected.

Variables may include a variable related to a battery state in each predetermined temperature segment. For example, variables may include unattended period (first unattended period) in a temperature segment of 10 to 15° C., unattended period (second unattended period) in a temperature segment of 15 to 20° ° C., and unattended period (third unattended period) in a temperature segment of 20 to 25° C.

Historical data may include historical data on a variable related to a battery state in each predetermined temperature segment. In such a case, state-related variables in adjacent temperature segments may be put together into a single variable. The computer may collectively treat variables in adjacent temperature segments as a single variable such that the correlation between high-accuracy estimated values obtained by using the multiple regression equation and simple estimated values becomes smaller.

The computer applies actual values of a variable included in historical data to a degradation contribution relation and obtains a capacity decrease corresponding to the actual values. The computer obtains an estimated value (simple estimated value) of full charge capacity after degradation by subtracting the respective capacity decreases corresponding to the actual values of N variables from an initial full charge capacity.

Variables may include a variable related to a battery electric vehicle state (travel distance, travel period, or the like) besides those related to a battery state. For a variable related to a battery state, a variable other than the variables illustrated in the embodiment may be adopted.

The method of creating an estimating equation disclosed by the present description may be performed by a computer or may be performed by a person.

Although specific examples of the present disclosure have been described in detail hereinabove, such specific examples are provided only for illustrative purposes and do not limit the scope of claims. The technique as described in claims includes various modifications of the illustrated specific examples and changes made thereto. The technical elements described in the present description or the drawings demonstrate technical usefulness thereof on a stand-alone basis or in various combinations, and are not limited to the combinations as described in claims of the application originally filed. The technique illustrated in the present description or the drawings can achieve a plurality of objects concurrently, and naturally has technical usefulness by achieving one of the objects.

What is claimed is:

1. A method of creating an estimating equation for a full charge capacity after degradation of a battery mounted in a battery electric vehicle, the method comprising:
a first step of obtaining a degradation contribution relation through an experiment or simulation, the degradation contribution relation representing a relation between each of N variables related to a state of the battery and a decrease from an initial value of the full charge capacity;
a second step of collecting historical data on the variables from L battery electric vehicles, and obtaining, by using the degradation contribution relation, a simple estimated value of the full charge capacity after degradation for each of the L battery electric vehicles;
a third step of calculating a correlation coefficient between L sets of the historical data on each variable and the L simple estimated values, and selecting, among the variables, M (M<N) variables having the correlation coefficient that exceeds a predetermined threshold value;
a fourth step of formulating, by using the selected variables, Equation 1 provided below by which a high-accuracy estimated value of the full charge capacity after degradation is obtained;
a fifth step of determining the coefficients and a constant by substituting K sets of the historical data among the L sets of the historical data into the variables of the Equation 1 and substituting K of the simple estimated values into a left side of Equation 1;
a sixth step of correcting the coefficients in such a manner that a correlation between (L−K) high-accuracy estimated values and the corresponding simple estimated values becomes stronger, the (L−K) high-accuracy estimated values being obtained by substituting (L−K) sets of the historical data into a right side of the Equation 1 including the determined coefficients and the determined constant; and
a seventh step of obtaining the Equation 1 using the corrected coefficients as the estimating equation.
$$\begin{matrix}[ Formula 2 ] & \\ High - accuracy estimated value = initial full charge capacity - {\sum }_{i = 1}^{M} ( coefficient ( i ) \times variable ( i ) ) + constant & ( Equation 1 )\end{matrix}$$

2. A method of estimating a full charge capacity after degradation of the battery by using the estimating equation according to claim 1.
